(19) United States
(12) Patent Application Publication
(10) Pub. No.: US 2024/0170320 A1
(43) Pub. Date: May 23, 2024

(54) DIE BONDING DEVICE, DIE BONDING METHOD AND VACUUM CONTROL METHOD FOR PICK-AND-PLACER THEREOF

(71) Applicant: Taiwan Semiconductor Manufacturing Company, Ltd., Hsinchu (TW)

(72) Inventors: Yan-Zuo TSAI, Hsinchu (TW); Yang-Chih HSUEH, Hsinchu (TW); Yung-Chi LIN, Hsinchu (TW)

(73) Assignee: Taiwan Semiconductor Manufacturing Company, Ltd., Hsinchu (TW)

(21) Appl. No.: 18/099,106

(22) Filed: Jan. 19, 2023

Related U.S. Application Data
(60) Provisional application No. 63/427,593, filed on Nov. 23, 2022.

(51) Int. Cl. H01L 21/683; H01L 21/67

(52) U.S. Cl. CPC H01L 21/6838; H01L 21/67144

(57) ABSTRACT

A die bonding device is provided to pick up a die and place the die on a carrier. The die bonding device includes a pick-and-placer and a vacuum generator. The pick-and-placer includes an adsorption surface, a first channel and a second channel, and the first channel and the second channel are not connected to each other. The vacuum generator includes a first vacuum pump and a second vacuum pump, the first vacuum pump is connected to the first channel via a pipeline, the second vacuum pump is connected to the second channel via another pipeline, the first vacuum pump and the second vacuum pump make the pick-and-placer adsorb the die to the adsorption surface during a vacuum holding period, and the first vacuum pump and the second vacuum pump respectively make the pick-and-placer release the die to the carrier sequentially in a vacuum release period.

### PRIORITY CLAIM AND CROSS-REFERENCE

This application claims the benefit of U.S. provisional application Ser. No. 63/427,593, filed Nov. 23, 2022, the subject matter of which is incorporated herein by reference.

### BACKGROUND

The system on integrated chip (SoIC) packaging technology adopted by the chip package manufacture is based on wafer-on-wafer (WoW) and chip-on-wafer (CoW) multi-chip stacking technologies, the dies are stacked in a face-to-face or face-to-back manner to connect to each other.

For SoIC pick-and-place bonding process, top die deformation control during bonding is the most important key factor of yield evaluation. Bonding condition of the pick-and-placer will also affect the quality of plane-to-plane bonding. Current pick-and-placers only have single vacuum channel for top die handling process. Top die vacuum on and off is the only one parameter to control the top die for chip on wafer bonding process. It needs to be improved further.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are schematic diagrams of a die bonding device and a die bonding method according to a comparative example.

FIGS. 2A to 2C are schematic diagrams of a die bonding device and a die bonding method according to an embodiment of the present disclosure, respectively.

FIG. 2D is a schematic plan view of the pick-and-placer of FIG. 2A according to an embodiment.

FIGS. 3A to 3D are schematic diagrams of a die bonding device and a die bonding method according to another embodiment of the present disclosure.

FIG. 3E is a schematic plan view of the pick-and-placer of FIG. 3A according to an embodiment.

FIGS. 4A to 4E are schematic diagrams of a die bonding device and a die bonding method according to another embodiment of the present disclosure.

FIG. 4F is a schematic plan view of the pick-and-placer of FIG. 4A according to an embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

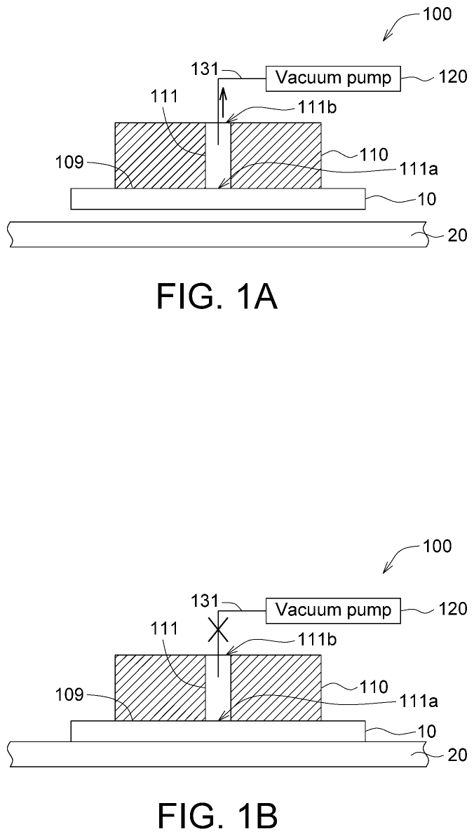

Please refer to FIGS. 1A and 1B, which are schematic diagrams of a die bonding device 100 and a die bonding method according to a comparative example. According to an example, the die bonding device 100 includes a pick-and-placer 110 and a vacuum pump 120. The pick-and-placer 110 can generally be used in a pick-and-place machine with a two-axis moving stage and a servo controller, such as the Datacon™ 2200 evo multi-chip die bonder offer by BE Semiconductor Industries N.V., Shibaura Mechatronics Co., Ltd., Model: TFC-6000, or similar machine. The pick-and-placer 110 can complete the pick-and-place operation of the die 10 through the movement of the robotic arm and numerical control. The pick-and-place machine and the robotic arm are known components, and will not be repeated here. The pick-and-placer 110 is used to pick up a die 10 and place the die 10 on a carrier 20. The carrier 20 (i.e., wafer) may comprise glass, silicon oxide, aluminum oxide, and the like, as examples. The thickness of the carrier 20 may be between about a few mils to several tens of mils and may comprise a diameter of about 300 mm in some embodiments. The carrier 20 functions as a fan-out carrier wafer during the packaging of semiconductor devices or dies. The die 10 may be a central processing unit (CPU) die, a graphics processing unit (GPU) die, a system-on-a-chip (SoC) unit die or a high bandwidth memory (HBM), a power management die (for example, power management integrated circuit (PMIC)), a radio frequency (RF) die, a sensor die, a micro-electro-mechanical-system (MEMS) die, a signal processing die (such as digital signal processor, DSP) etc. The dies are collected and stored in a waffle pack or on a dicing tape, and can be picked up by the pick-and-placer 110, the present disclosure is not limited thereto.

In one embodiment, before placing the die 10 on the carrier 20, a bonding film (not shown) can be formed on the carrier 20. The bonding film can be a silicon dioxide film, and its thickness is, for example, between 0.1 micron and 1 micron. The bonding film can generate a weak Van der Waals force between the die 10 and the carrier 20 due to direct room temperature bonding, so that the bonding surface of the die 10 can be completely attached to the bonding film, reducing the probability of voids due to incomplete bonding of the bonding surfaces of the die 10 to the carrier 20.

Referring to FIG. 1A, the pick-and-placer 110 includes an adsorption surface 109, a suction port 111a and an outlet port 111b. The suction port 111a is connected with the outlet 111b to form a channel 111, and the channel 111 is located in the central area of the pick-and-placer 110 to serve as a vacuum sucker. The vacuum pump 120 is connected to the channel 111 via a pipeline 131, so that the pick-and-placer 110 adsorbs the die 10 to the adsorption surface 109 during a vacuum holding period. In addition, referring to FIG. 1B, after the vacuum pump 120 is turned off to release the vacuum in the channel 111, the pick-and-placer 110 can release the die 10 to the carrier 20 during a vacuum release period.

Since the die warpage is high, top die deformation could not be well controlled by single vacuum channel 111, so that the vacuum bulge induced by non-smooth die contact is randomly occurred between the die 10 and the carrier 20.

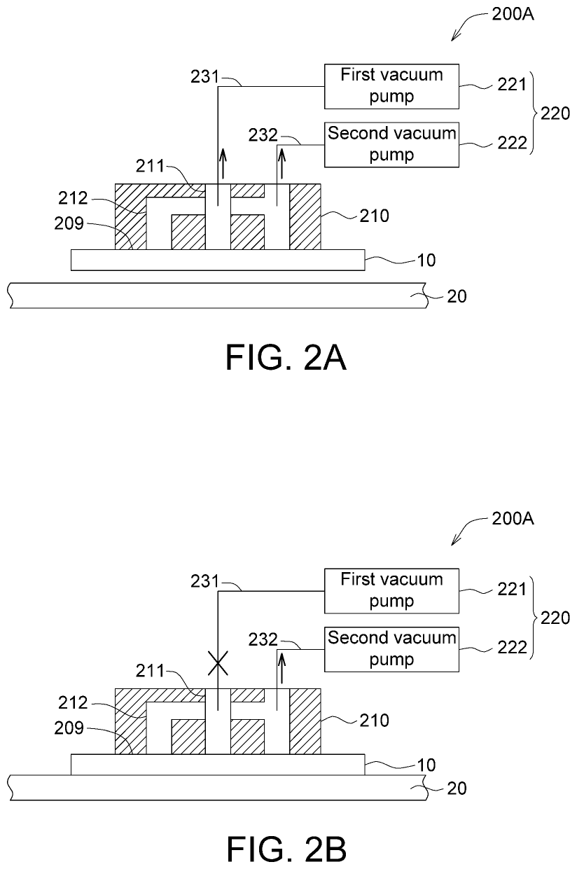

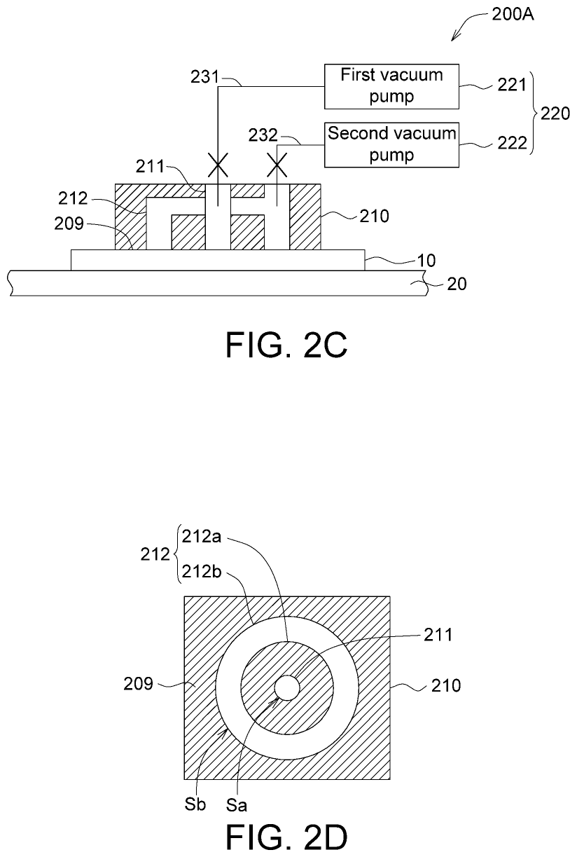

Please refer to FIGS. 2A to 2C, which are schematic diagrams of a die bonding device 200A and a die bonding method according to an embodiment of the present disclosure. The die bonding device 200A is used to pick up a die 10 and place the die 10 on a carrier 20. The descriptions of the die 10 and the carrier 20 are shown as above, and are not repeated here.

The difference from the above comparative example is that the die bonding device 200A of the present embodiment includes a pick-and-placer 210 and a vacuum generator 220. The pick-and-placer 210 includes an adsorption surface 209, a first channel 211 and a second channel 212. The first channel 211 and the second channel 212 are not connected to each other. The vacuum generator 220 includes a first vacuum pump 221 and a second vacuum pump 222, the first vacuum pump 221 is connected to the first channel 211 via a pipeline 231, and the second vacuum pump 222 is connected to the second channel 212 via another pipeline 232. As shown in FIG. 2A, after the first vacuum pump 221 and the second vacuum pump 222 is turned on to vacuum, the first vacuum pump 221 and the second vacuum pump 222 make the pick-and-placer 210 suck the die 10 to the adsorption surface 209 during a vacuum holding period. In addition, as shown in FIG. 2B, after the first vacuum pump 221 is turned off to release the vacuum in the first channel 211, the first channel 211 of the pick-and-placer 210 no longer generates a vacuum suction force on the die 10, so that the pick-and-placer 210 adsorbs the die 10 to the adsorption surface 209 only by the vacuum suction force in the second channel 212. Next, as shown in FIG. 2C, after the second vacuum pump 222 is turned off to release the vacuum in the second channel 212, the second channel 212 of the pick-and-placer 210 no longer generates a vacuum suction force on the die 10, so that the pick-and-placer 210 cannot adsorb the die 10, and the die 10 is released to the carrier 20.

In one embodiment, the first vacuum pump 221 is turned off at a first time point, for example, before releasing the die 10 to the carrier 20 or after releasing the die 10 to the carrier 20, and then, the second vacuum pump 222 is turned off at a second time point after releasing the die 10 to the carrier 20 and the second time point is later than the first time point. For example, the first vacuum pump 221 is turned off at a first time point (e.g., the first second) after releasing the die 10 to the carrier 20, and then, the second vacuum pump 222 is turned off at a second time point (e.g., the second second) after the die 10 is released from the carrier 20, the first time point and the second time point are separated by 1 second or several seconds, which is not limited in the present disclosure.

Referring to FIG. 2D, which is a schematic plan view of the pick-and-placer 210 of FIG. 2A according to an embodiment. The first channel 211 and the second channel 212 of the pick-and-placer 210 have a first suction port Sa and a second suction port Sb, respectively, and the first suction port Sa and the second suction port Sb are located in a central area and a peripheral area of the adsorption surface 209. The first suction port Sa is, for example, a circular hole, and the second suction port Sb is, for example, an annular slot, which surrounds the first suction port Sa. The center of the first suction port Sa is substantially aligned with the geometric center of the pick-and-placer 210, the second suction port Sb has an inner ring 212a and an outer ring 212b relative to the center of the first suction port Sa, and the region enclosed by the inner ring 212a and the outer ring 212b is the area of the second suction port Sb. The area of the second suction port Sb is, for example, twice or three times the area of the first suction port Sa. The greater the area of the first suction port Sa and the second suction port Sb, the greater the suction area between the pick-and-placer 210 and the die 10, but the present disclosure is not limited thereto.

As seen from the above description, the first vacuum pump 221 and the second vacuum pump 222 respectively make the pick-and-placer 210 release vacuum in the corresponding channels from the inside to the outside at different time points (i.e., the first time point and the second time point), so as to place the die 10 on the carrier 20. Compared with the single vacuum channel 111 of FIG. 1A, the present embodiment adopts multiple vacuum channels with time on/off control, smooth bonding wave propagation by well controlled top die deformation is achieved by multiple vacuum channels of die bonding device 200A of the present embodiment. Therefore, vacuum bulge induced by the non-smooth bonding die contact is eliminated.

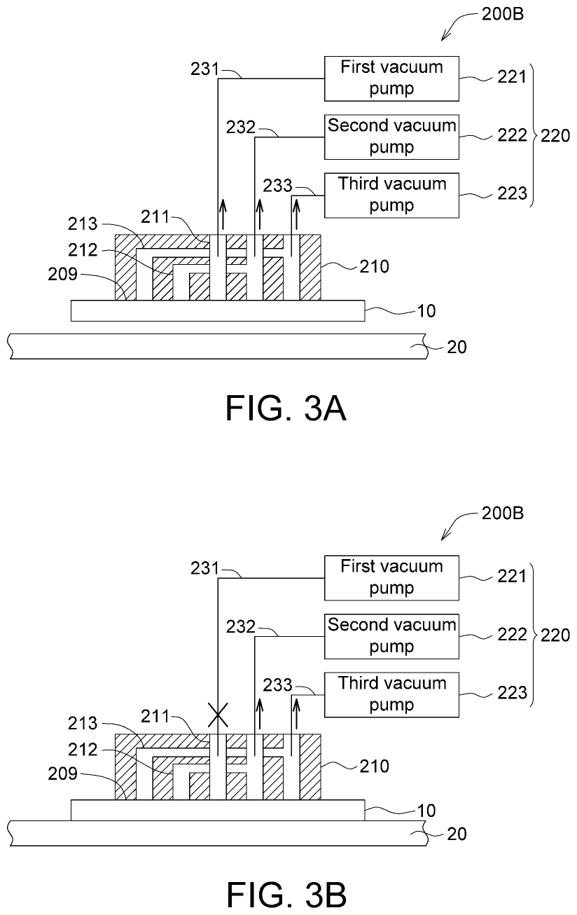

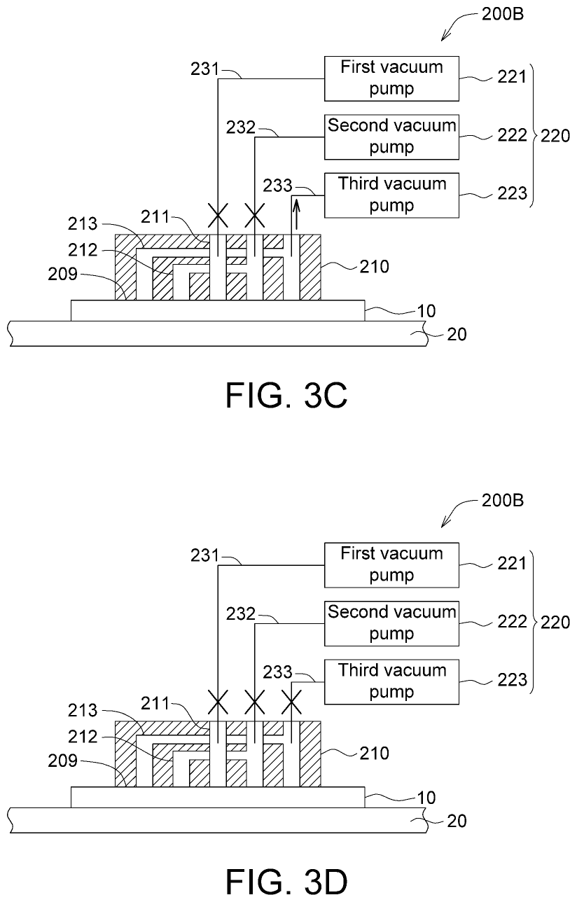

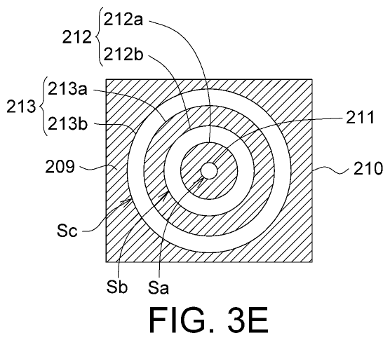

Referring to FIGS. 3A to 3D, which are schematic diagrams of a die bonding device 200B and a die bonding method according to another embodiment of the present disclosure. The die bonding device 200B is used to pick up a die 10 and place the die 10 on a carrier 20. The descriptions of the die 10 and the carrier 20 are shown as above, and will not be repeated here.

The difference from the above comparative example is that the die bonding device 200B of the present embodiment includes a pick-and-placer 210 and a vacuum generator 220. The pick-and-placer 210 includes an adsorption surface 209, a first channel 211, a second channel 212 and a third channel 213. The first channel 211, the second channel 212 and the third channel 213 are not connected to each other. The vacuum generator 220 includes a first vacuum pump 221, a second vacuum pump 222 and a third vacuum pump 223. The first vacuum pump 221 is connected to the first channel 211 via a pipeline 231, and the second vacuum pump 222 is connected to the second channel 212 via another pipeline 232, and the third vacuum pump 223 is connected to the third channel 213 via another pipeline 233. As shown in FIG. 3A, after the first vacuum pump 221, the second vacuum pump 222 and the third vacuum pump 223 are each turned on, the first vacuum pump 221, the second vacuum pump 222 and the third vacuum pump 223 make the pick-and-placer 210 adsorbs the die 10 to the adsorption surface 209 during a vacuum holding period. In addition, as shown in FIG. 3B, after the first vacuum pump 221 is turned off to release the vacuum in the first channel 211, the first channel 211 of the pick-and-placer 210 no longer generates a vacuum suction force on the die 10, so that the pick-and-placer 210 adsorbs the die 10 to the adsorption surface 209 only by the vacuum suction forces in the second channel 212 and the third channel 213. Next, as shown in FIG. 3C, after the second vacuum pump 222 is turned off to release the vacuum in the second channel 212, the second channel 212 of the pick-and-placer 210 no longer generates a vacuum suction force on the die 10, so that the pick-and-placer 210 adsorbs the die 10 to the adsorption surface 209 only by the vacuum suction force in the third channel 213. Next, as shown in FIG. 3D, after the third vacuum pump 223 is turned off to release the vacuum in the third channel 213, the pick-and-placer 210 cannot adsorb the die 10, so that the die 10 is released to the carrier 20.

In one embodiment, the first vacuum pump 221 is turned off at a first time point, for example, before releasing the die 10 to the carrier 20 or after releasing the die 10 to the carrier 20, and then, the second vacuum pump 222 is turned off at a second time point after releasing the die 10 to the carrier 20 and the second time point is later than the first time point. Next, the third vacuum pump 223 is turned off at a third time point after releasing the die 10 to the carrier 20 and the third time point is later than the second time point. For example, the first vacuum pump 221 is turned off at a first time point (e.g., the first second) after releasing the die 10 to the carrier 20, and then, the second vacuum pump 222 is turned off at a second time point (e.g., the second second) after releasing the die 10 to the carrier 20, and then, the third vacuum pump 223 is turned off at a third time point (e.g., the third second) after releasing the die 10 to the carrier 20. The first time point, the second time point and the third time point are separated by 1 second or several seconds, which is not limited in the present disclosure.

Referring to FIG. 3E, which is a schematic plan view of the pick-and-placer 210 of FIG. 3A according to an embodiment. The first to third channels 211-213 of the pick-and-placer 210 correspondingly have a first suction port Sa, a second suction port Sb and a third suction port Sc, and the first suction port Sa, the second suction port Sb and the third suction port Sc are correspondingly located in a central area, a first peripheral area and a second peripheral area of the adsorption surface 209. The first suction port Sa is, for example, a circular hole, and the second suction port Sb is, for example, an annular slot, which surrounds the first suction port Sa. The third suction port Sc is, for example, a larger annular slot (e.g., oval), which surrounds the first suction port Sa and the second suction port Sb. The center of the first suction port Sa is substantially aligned with the geometric center of the pick-and-placer 210, each of the second suction port Sb and the third suction port Sc has an inner ring 212a/213a and an outer ring 212b/213b relative to the center of the first suction port Sa, and the regions enclosed by the inner ring and the outer ring are the areas of the second suction port Sb and the third suction port Sc, respectively. The areas of the second suction port Sb and the third suction port Sc are, for example, twice or three times or more of the area of the first suction port Sa, and the greater the area of the first suction port Sa, the second suction port Sb, and the third suction port Sc is, the greater the adsorption area between the pick-and-placer 210 and the die 10 is, but this is not limited in the present disclosure.

As seen from the above description, the first vacuum pump 221, the second vacuum pump 222 and the third vacuum pump 223 make the pick-and-placer 210 release the vacuum in the corresponding channels from the inside to the outside at different time points (i.e., the first time point, the second time point and the third time point), so as to place the die 10 on the carrier 20. Compared with the single vacuum channel 111 of FIG. 1A, the present embodiment adopts multiple vacuum channels with time on/off control, a smooth bonding wave propagation by well controlled top die deformation is achieved by multiple vacuum channels of the die bonding device 200B of the present embodiment. Therefore, vacuum bulge induced by a non-smooth bonding die contact is eliminated.

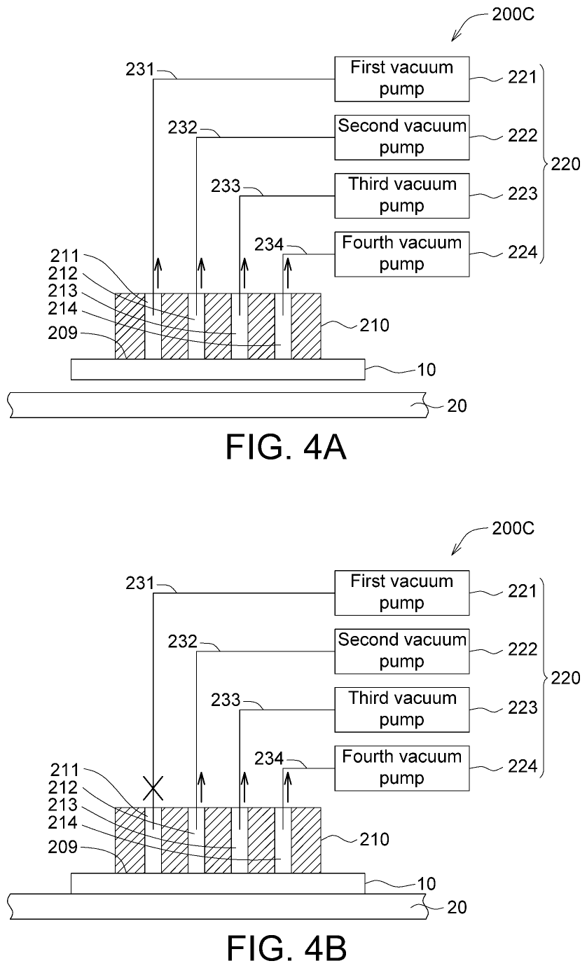

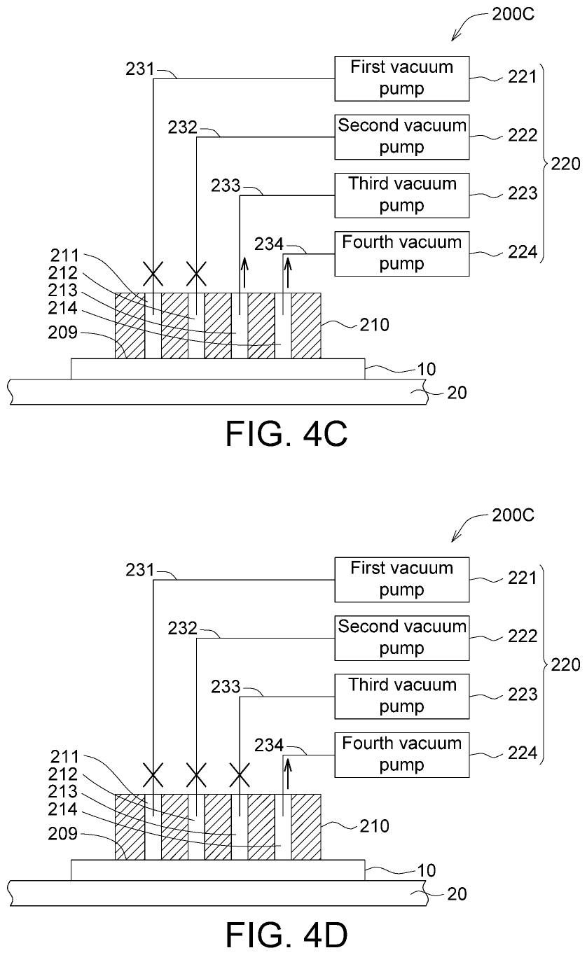

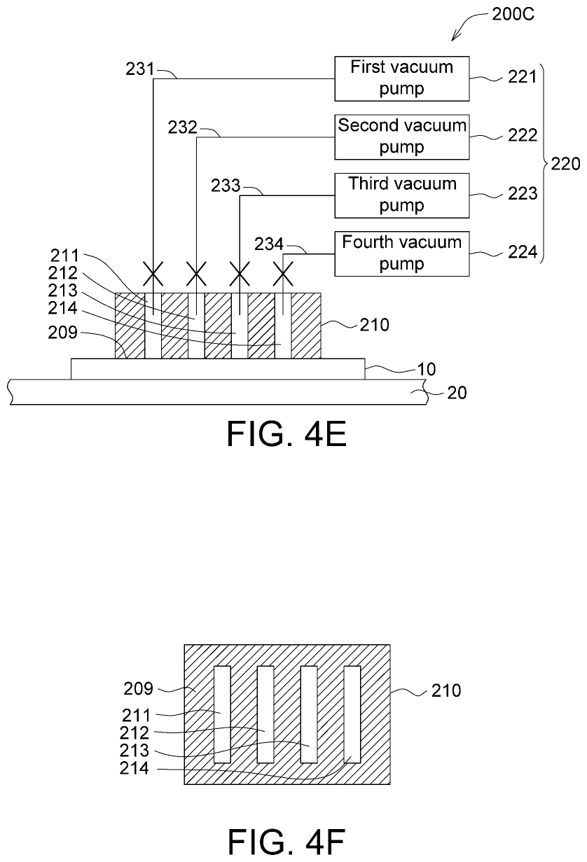

Referring to FIGS. 4A to 4E, which are schematic diagrams of a die bonding device 200C and a die bonding method according to another embodiment of the present disclosure. The die bonding device 200C is used to pick up a die 10 and place the die 10 on a carrier 20. The descriptions of the die 10 and the carrier 20 are shown as above, and will not be repeated here.

The difference from the above comparative example is that the die bonding device 200C of this embodiment includes a pick-and-placer 210 and a vacuum generator 220. The pick-and-placer 210 includes an adsorption surface 209, a first channel 211, a second channel 212, a third channel 213 and a fourth channel 214. The first channel 211, the second channel 212, the third channel 213 and the fourth channel 214 are not connected to each other. The vacuum generator 220 includes a first vacuum pump 221, a second vacuum pump 222, a third vacuum pump 223 and a fourth vacuum pump 224. The first vacuum pump 221 is connected to the first channel 211 via a pipeline 231, and the second vacuum pump 222 is connected to the second channel 212 via another pipeline 232, the third vacuum pump 223 is connected to the third channel 213 via another pipeline 233, and the fourth vacuum pump 224 is connected to the fourth channel 214 via another pipeline 234. As shown in FIG. 4A, after the first vacuum pump 221, the second vacuum pump 222, the third vacuum pump 223 and the fourth vacuum pump 224 are each turned on, the first vacuum pump 221, the second vacuum pump 222, and the third vacuum pump 223 and the fourth vacuum pump 224 make the pick-and-placer 210 adsorb the die 10 to the adsorption surface 209 during a vacuum holding period. In addition, as shown in FIG. 4B, after the first vacuum pump 221 is turned off to release the vacuum in the first channel 211, the first channel 211 of the pick-and-placer 210 no longer generates a vacuum suction force on the die 10, so that the pick-and-placer 210 adsorbs the die 10 to the adsorption surface 209 only by the vacuum suction forces in the second channel 212, the third channel 213 and the fourth channel 214. Next, as shown in FIG. 4C, after the second vacuum pump 222 is turned off to release the vacuum in the second channel 212, the second channel 212 of the pick-and-placer 210 no longer generates a vacuum suction force on the die 10, so that the pick-and-placer 210 adsorbs the die 10 to the adsorption surface 209 only by the vacuum suction forces in the third channel 213 and the fourth channel 214. Next, as shown in FIG. 4D, after the third vacuum pump 223 is turned off to release the vacuum in the third channel 213, the pick-and-placer 210 adsorbs the die 10 to the adsorption surface 209 only by the vacuum suction force in the fourth channel 214. Next, as shown in FIG. 4E, after the fourth vacuum pump 224 is turned off to release the vacuum in the fourth channel 214, the pick-and-placer 210 cannot adsorb the die 10, and the die 10 is released to the carrier 20.

In one embodiment, the first vacuum pump 221 is turned off at a first time point, for example, before releasing the die 10 to the carrier 20 or after releasing the die 10 to the carrier 20, and then, the second vacuum pump 222 is turned off at a second time point after releasing the die 10 to the carrier 20 and the second time point is later than the first time point. Next, the third vacuum pump 223 is turned off at a third time point after releasing the die 10 to the carrier 20 and the third time is later than the second time point. Next, the fourth vacuum pump 224 is turned off at a fourth time point after releasing the die 10 to the carrier 20 and the fourth time point is later than the third time point. For example, the first vacuum pump 221 is turned off at a first time point (e.g., the first second) after releasing the die 10 to the carrier 20, and then, the second vacuum pump 222 is turned off at a second time point (e.g., the second second) after releasing the die 10 to the carrier 20, and then the third vacuum pump 223 is turned off at a third time point (e.g., the third second) after releasing the die 10 to the carrier 20, and then the fourth vacuum pump 224 is turned off after releasing the die 10 to the carrier 20 The fourth vacuum pump 224 is turned off at a fourth time point (e.g., the fourth second). The first time point, the second time point, the third time point and the fourth time point are separated by one second or several seconds, which is not limited in the present disclosure.

Referring to FIG. 4F, which is a schematic plan view of the pick-and-placer 210 of FIG. 4A according to an embodiment. The first to fourth channels 211-214 of the pick-and-placer 210 correspondingly have a first suction port Sa, a second suction port Sb, a third suction port Sc and a fourth suction port Sd, and the first suction port Sa and the second suction port Sb, the third suction port Sc and the fourth suction port Sd are correspondingly located in four side-by-side regions of the adsorption surface 209 (for example, arranged from left to right or from inside to outside). The first suction port Sa, the second suction port Sb, the third suction port Sc, and the fourth suction port Sd are, for example, four elongated holes having substantially the same size or other shapes. The greater the area of the first suction port Sa, the second suction port Sb, the third suction port Sc and the fourth suction port Sd is, the greater the suction area between the pick-and-placer 210 and the die 10 is, and the number of suction ports may be two, three or more, but not limited to four. The port design of the first to fourth channels 211-214 can also adopt the design of the annular slots in the above-mentioned FIG. 2D and FIG. 3E or the design of the combination of the elongated holes and the annular slots, which is not limited in the present disclosure.

As seen from the above description, the first vacuum pump 221, the second vacuum pump 222, the third vacuum pump 223 and the fourth vacuum pump 224 make the pick-and-placer 210 release the vacuum in the corresponding channel at different time points (i.e., the first time point, the second time point, the third time point and the fourth time point) sequentially to place the die 10 on the carrier 20. Compared with the single vacuum channel 111 of FIG. 1A, the present embodiment adopts multiple vacuum channels with time on/off control, and a smooth wave propagation by well controlled top die deformation is achieved by multiple vacuum channels of the die bonding device of the present embodiment. Therefore, a vacuum bulge induced by a non-smooth die bonding contact is eliminated.

The present disclosure provides a die bonding device, a die bonding method, and a vacuum control method for a pick-and-placer thereof, which can provide dual vacuum channels, three vacuum channels or even more multiple vacuum channels for the pick-and-placer to pick up the die and place the die on the carrier. Regardless of whether incoming die warpage is high or low, top die deformation could be well controlled by multiple vacuum channels. In addition, a smooth bonding wave propagation is also achieved by different vacuum channel release timing control to eliminate the vacuum bulge induced by non-smooth die contact.

According to some embodiments of the present disclosure, a die bonding device is provided to pick up a die and place the die on a carrier. The die bonding device includes a pick-and-placer and a vacuum generator. The pick-and-placer includes an adsorption surface, a first channel and a second channel, and the first channel and the second channel are not connected to each other. The vacuum generator includes a first vacuum pump and a second vacuum pump, the first vacuum pump is connected to the first channel via a pipeline, the second vacuum pump is connected to the second channel via another pipeline, the first vacuum pump and the second vacuum pump make the pick-and-placer adsorb the die to the adsorption surface during a vacuum holding period, and the first vacuum pump and the second vacuum pump respectively make the pick-and-placer release the die to the carrier sequentially in a vacuum release period.

According to some embodiments of the present disclosure, a die bonding method is provided, which includes the following steps. A die is provided, and the die is adsorbed by a pick-and-placer. The pick-and-placer includes an adsorption surface, a first channel and a second channel, and the first channel and the second channel are not connected to each other. A first vacuum pump and a second vacuum pump are used to make the pick-and-placer adsorb the die to the adsorption surface during a vacuum holding period, wherein the first vacuum pump is connected to the first channel via a pipeline, and the second vacuum pump is connected to the second channel via another pipeline. The die is placed on a carrier board, and the first vacuum pump and the second vacuum pump are controlled to be turned off at different time points, so that the pick-and-placer releases the die to the carrier sequentially during a vacuum release period.

According to some embodiments of the present disclosure, a vacuum control method for a pick-and-placer is provided, which includes the following steps. a plurality of vacuum pumps is controlled to turn on and enables the pick-and-placer to generate a plurality of vacuum channels during a die pick-up period. The plurality of vacuum pumps is controlled to turn off at different time points, so that the pick-and-placer releases a die sequentially during a vacuum release period.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A die bonding device to pick up a die and place the die on a carrier, the die bonding device comprising:
a pick-and-placer, the pick-and-placer comprising an adsorption surface, a first channel and a second channel, the first channel and the second channel are not connected to each other; and
a vacuum generator comprising a first vacuum pump and a second vacuum pump, wherein the first vacuum pump is connected to the first channel via a pipeline, the second vacuum pump is connected to the second channel via another pipeline, the first vacuum pump and the second vacuum pump make the pick-and-placer adsorb the die to the adsorption surface during a vacuum holding period, and the first vacuum pump and the second vacuum pump respectively make the pick-and-placer release the die to the carrier sequentially during a vacuum release period.

2. The die bonding device according to claim 1, wherein the first vacuum pump and the second vacuum pump are turned off at a first time point and a second time point, respectively, and the second time point is later than the first time point.

3. The die bonding device according to claim 2, wherein the first time point is before releasing the die to the carrier.

4. The die bonding device according to claim 2, wherein the first time point is after releasing the die to the carrier.

5. The die bonding device according to claim 2, wherein the first time point and the second time point are separated by 1 second or several seconds.

6. The die bonding device according to claim 1, wherein the first channel and the second channel correspondingly have a first suction port and a second suction port, and the first suction port and the second suction port are located at a central area and a peripheral area of the adsorption surface, respectively.

7. The die bonding device according to claim 6, wherein the first suction port is a circular hole, the second suction port is an annular slot, and the second suction port surrounds the first suction port.

8. The die bonding device according to claim 2, wherein the pick-and-placer further comprises a third channel, the vacuum generator further comprises a third vacuum pump, and the third vacuum pump is connected to the third channel via another pipeline, the first channel, the second channel and the third channel are not connected to each other.

9. The die bonding device according to claim 8, wherein the third vacuum pump makes the pick-and-placer adsorb the die to the adsorption surface during the vacuum holding period, and the third vacuum pump is turned off at a third time point, the third time point is later than the second time point.

10. The die bonding device according to claim 8, wherein the third channel has a third suction port, the third suction port is located in a peripheral area of the adsorption surface, and the third suction port is an annular slot, the third suction port surrounds the first channel and the second channel.

11. The die bonding device according to claim 2, wherein the pick-and-placer further includes a third channel and a fourth channel, the vacuum generator further includes a third vacuum pump and a fourth vacuum pump, the third vacuum pump is connected to the third channel via another pipeline, the fourth vacuum pump is connected to the fourth channel via another pipeline, the first channel, the second channel, the third channel and the fourth channel are not connected to each other.

12. The die bonding device according to claim 11, wherein the third vacuum pump and the fourth vacuum pump make the pick-and-placer adsorb the die to the suction surface during the vacuum holding period, and the third vacuum pump and the fourth vacuum pump are respectively turned off at a third time point and a fourth time point, the third time point is later than the second time point, and the fourth time point is later than the third time point.

13. The die bonding device according to claim 11, wherein the first channel, the second channel, the third channel, and the fourth channel correspondingly have a first suction port, a second suction port, a third suction port and a fourth suction port, the first suction port, the second suction port, the third suction port and the fourth suction port are sequentially arranged on the adsorption surface.

14. A die bonding method, comprising:
providing a die, the die being adsorbed by a pick-and-placer, the pick-and-placer comprising an adsorption surface, a first channel and a second channel, wherein the first channel and the second channel are not connected to each other;
using a first vacuum pump and a second vacuum pump to make the pick-and-placer adsorb the die to the adsorption surface during a vacuum holding period, wherein the first vacuum pump is connected to the first channel via a pipeline, and the second vacuum pump is connected to the second channel via another pipeline; and
placing the die on a carrier, and the first vacuum pump and the second vacuum pump are controlled to turn off at different time points, so that the pick-and-placer releases the die to the carrier sequentially during a vacuum release period.

15. The die bonding method according to claim 14, wherein the first vacuum pump is turned off at a first time point, and the second vacuum pump is turned off at a second time point, and the second time point is later than the first time point.

16. The die bonding method according to claim 14, wherein the first channel and the second channel correspondingly have a first suction port and a second suction port, and the first suction port and the second suction port are located in the a central area and a surrounding area of the adsorption surface, respectively.

17. The die bonding method according to claim 16, wherein the first suction port is a circular hole, the second suction port is an annular slot, and the second suction port surrounds the first suction port.

18. The die bonding method according to claim 16, wherein the first suction port and the second suction port are elongated holes arranged side by side.

19. A vacuum control method for a pick-and-placer, comprising:
controlling a plurality of vacuum pumps to turn on so that the pick-and-placer generates a plurality of vacuum channels during a die pick-up period; and
controlling the plurality of vacuum pumps to turn off at different time points so that the pick-and-placer releases a die sequentially during a vacuum release period.

20. The vacuum control method according to claim 19, wherein a first vacuum pump of the plurality of vacuum pumps is turned off at a first time point before or after releasing the die to a carrier, and a second vacuum pump of the plurality of vacuum pumps is turned off at a second time point after the first time point, and the first time point and the second time point are separated by 1 second or several seconds.
